(19) United States
(12) Patent Application Publication
(10) Pub. No.: US 2019/0229044 A1
(43) Pub. Date: Jul. 25, 2019

(54) LEAD FRAME WITH PLATED LEAD TIPS

(71) Applicant: NXP B.V., Eidhoven (NL)

(72) Inventors: AMORNTHEP SAIYAJITARA, Bangkok (TH); Wiwat Tanwongwan, Bangkok (TH); Chanon Suwankasab, Pathumthani (TH); Ekapong Tangpattanasaeree, Bangkok (TH)

(21) Appl. No.: 15/878,292

(22) Filed: Jan. 23, 2018

(51) Int. Cl. H01L 23/495; H01L 21/48

(52) U.S. Cl. CPC H01L 23/49582; H01L 21/4842; H01L 24/48; H01L 23/49548; H01L 23/49565

(57) ABSTRACT

A lead frame is formed with exposed lead tips. The leads are not attached at their tips to any of a tie bar, a dam bar or an end bar, so when the lead frame is plated, the lead tips are plated. During packaging, after die attach and molding, when the lead frame is cut from the frame assembly, the lead tips are not cut, so the plating remains on the tips. This improves solder joint reliability when the package is mounted on a PCB. The lead frame has connection bars that run parallel to the leads from the tie bar to the end bar. The connection bars provide stability to the leads during wire bonding, but are cut from the lead frame after wire bonding.

### BACKGROUND

The present invention generally relates to a lead frame used for assembling a semiconductor device and a method for assembling a semiconductor device using the lead frame, and, more particularly, to a lead frame with plated lead tips.

FIG. 1 is a top plan view of part of a conventional lead frame strip 10, showing two lead frames 12 and 14, during assembly of a semiconductor device. The lead frame strip 10 typically comprises copper or copper foil that is plated or at least partially plated with metals such as tin, nickel, and/or palladium, which inhibit corrosion. The lead frames 12 and 14 each comprise a die pad 16 surrounded by a plurality of leads or lead fingers 18. The lead fingers 18 have a proximal end 20 near to the die pad 16, a distal end 22 spaced from the die pad 16, and a central portion 24 that connects the proximal and distal ends 20 and 22. The die pad 16 is attached to the central frame with tie bars 26. A dam bar 28 extends perpendicular to the leads 18 and is connected to the central portion 24 of the leads 18, and an end bar 30 also extends perpendicular to the leads 18 and is connected to the distal ends 22 of the leads 18.

During the assembly process, dies 32 are attached to the lead frames 12 and 14, and electrodes on the dies 32 are electrically connected to respective ones of the leads 18. The lead frame 14 shows bond wires 34 being used to electrically connect the die 32 with the proximal ends 20 of the leads 18. After wire bonding, the die 32, bond wires 34 and proximal ends 20 of the leads 18 are covered with a molding compound (not shown), where the molding compound will extend to the dam bar 28. The molding compound provides electrical and mechanical protection to the semiconductor die 32, the lead frame 14 and the connections 34 therebetween. After molding, the lead frame 14 is trimmed, whereby the dam bar 28 is cut away, and the distal ends 22 of the leads 18 are separated from the end bar 30 by cutting along the dashed line A-A.

FIG. 2 shows a conventional semiconductor device 40 being mounted on a printed circuit board (PCB) 42, which comprises a molded body 44 and the distal ends 22 of the leads 18 extending outwardly from the molded body 44. The leads 18 are electrically connected to pads 46 of the PCB 42 with solder 48. However, since the leads 18 were cut from the lead frame 14 along the line A-A, the tips 50 of the leads 18 were cut and exposed. That is, the bare copper of the lead frame is exposed, and as is well known, bare copper is readily corroded and therefore may not hold the solder 48, which in turn can make for a weak solder joint.

One solution is to plate the lead frame tips 50 after separating the assembled devices 40 from the lead frame strip 10, but this requires an additional plating step, which adds to the manufacturing time and cost. Accordingly, it would be advantageous to be able to assemble semiconductor devices where the copper base of the lead frame is not exposed during trim and form.

### BRIEF DESCRIPTION OF THE DRAWINGS

So that the manner in which the features of the present invention can be understood in detail, a detailed description of the invention is provided below with reference to embodiments, some of which are illustrated in the appended drawings. It is to be noted, however, that the appended drawings illustrate only typical embodiments of the invention and are therefore not to be considered limiting of its scope, for the invention may admit to other equally effective embodiments. The drawings are for facilitating an understanding of the invention and thus are not necessarily drawn to scale. Advantages of the subject matter claimed will become apparent to those skilled in the art upon reading this description in conjunction with the accompanying drawings, in which like reference numerals have been used to designate like elements, and in which:

FIG. 1 is an enlarged top plan view of a portion of a conventional lead frame strip used to assemble leaded semiconductor devices;

FIG. 2 is an enlarged perspective view of a conventional semiconductor device, assembled using a lead frame of the lead frame strip of FIG. 1, attached to a printed circuit board;

FIG. 3 is an enlarged top plan view of a lead frame for a semiconductor device in accordance with an exemplary embodiment of the present invention;

FIG. 4 is an enlarged perspective view of a portion of a semiconductor device, assembled using the lead frame of FIG. 3, attached to a printed circuit board;

FIG. 5 is a flow diagram illustrating steps of assembling a semiconductor device in accordance with an exemplary embodiment of the present invention;

FIG. 6 is a top plan view of a portion of a convention lead frame; and

FIG. 7 is a top plan view of a portion of a lead frame in accordance with an embodiment of the present invention.

### DETAILED DESCRIPTION

In one embodiment, the present invention provides a lead frame for a semiconductor device. The lead frame has a central area for receiving an integrated circuit die, and a plurality of leads that extend away from at least one lateral side of the central area. The leads each have a proximal end near to the central receiving area, a distal end, and a central portion connecting the proximal and distal ends. A dam bar extends generally perpendicular to the leads and connects the leads at the central portions thereof. An end bar extends generally perpendicular to the leads and parallel to the dam bar. The end bar is located near to, but spaced from, the distal ends of the leads. There also are one or more connection bars extending from the end bar to the dam bar.

In another embodiment, the present invention provides a method of assembling a semiconductor device. The method includes providing a lead frame having a central area for receiving an integrated circuit die, and a plurality of leads that extend away from at least one lateral side of the central area. The leads each have a proximal end near to the central receiving area, a distal end, and a central portion connecting the proximal and distal ends. The lead frame further comprises a dam bar that extends generally perpendicular to the leads and connects the leads at the central portions thereof, an end bar that extends generally perpendicular to the leads and parallel to the dam bar, and one or more connection bars extending from the end bar to the dam bar. The end bar is located near to, but spaced from, the distal ends of the leads. At least the distal ends of the leads are plated with a non-corroding material.

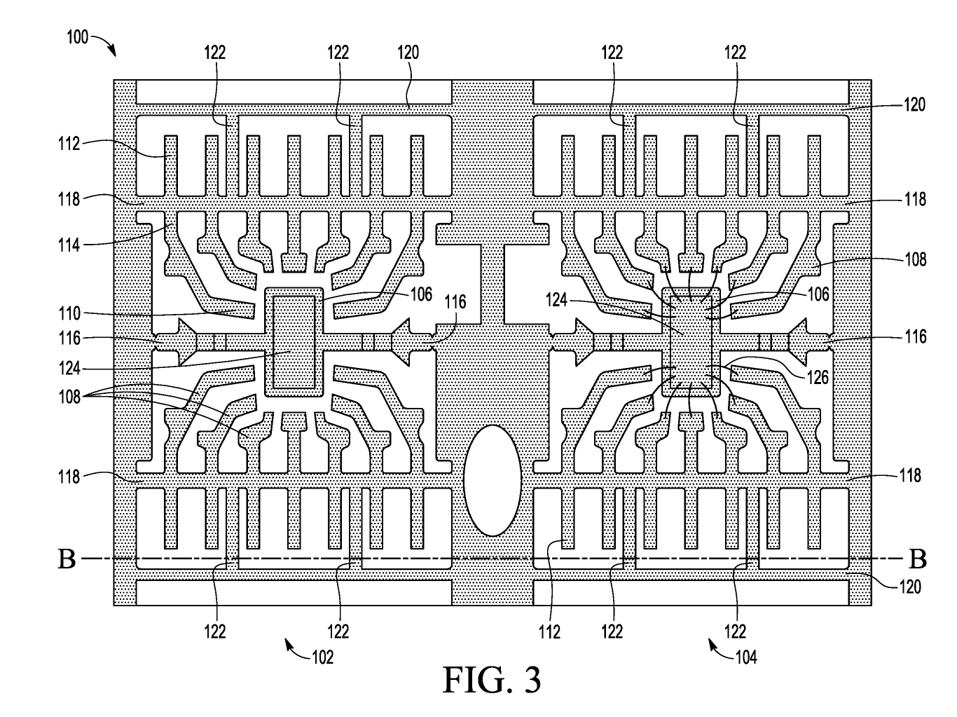

Referring now to FIG. 3, an enlarged top plan view of portion of a lead frame strip 100 for a semiconductor device in accordance with an exemplary embodiment of the present invention is shown. The lead frame strip 100 includes a plurality of lead frames, two of which are shown 102 and 104. The lead frames may be arranged is a single strip or as an array, as are known in the art. The lead frame 112 and the lead frame 114 are shown during assembly of a semiconductor device.

The lead frame strip 100 may comprise a conductive base layer, such as copper or copper foil, that is plated or at least partially plated with metals or metal alloy, such as tin, nickel, and/or palladium, which inhibit corrosion and provide for a good, solderable surface. In the presently preferred embodiment, the lead frames 112 and 114 are comprised of copper, and at least the distal ends of the leads are plated with a non-corroding material, such as Nickel and Palladium.

The lead frames 102 and 104 each comprise a central die receiving area 106, which in this embodiment is a die pad. The die pad 106 is sized and shaped to receive a semiconductor die and thus, the size of the die pad generally is based on the size of the die. In the embodiment shown, the die pad 106 is rectangular, but this is not a requirement. The lead frames 102 and 104 also have a plurality of leads 108 that extend away from at least one lateral side of the central area or die pad 106. In the embodiment shown, the leads 108 extend away from two of the lateral sides of the die pad 106. However, as will be understood by those of skill in the art, the leads 108 may surround the die pad 106, thus extending away from all four sides of the die flag 106. The leads 108 each have a proximal end 110 near to but spaced from the central receiving area 106, a distal end 112, and a central portion 114 connecting the proximal and distal ends.

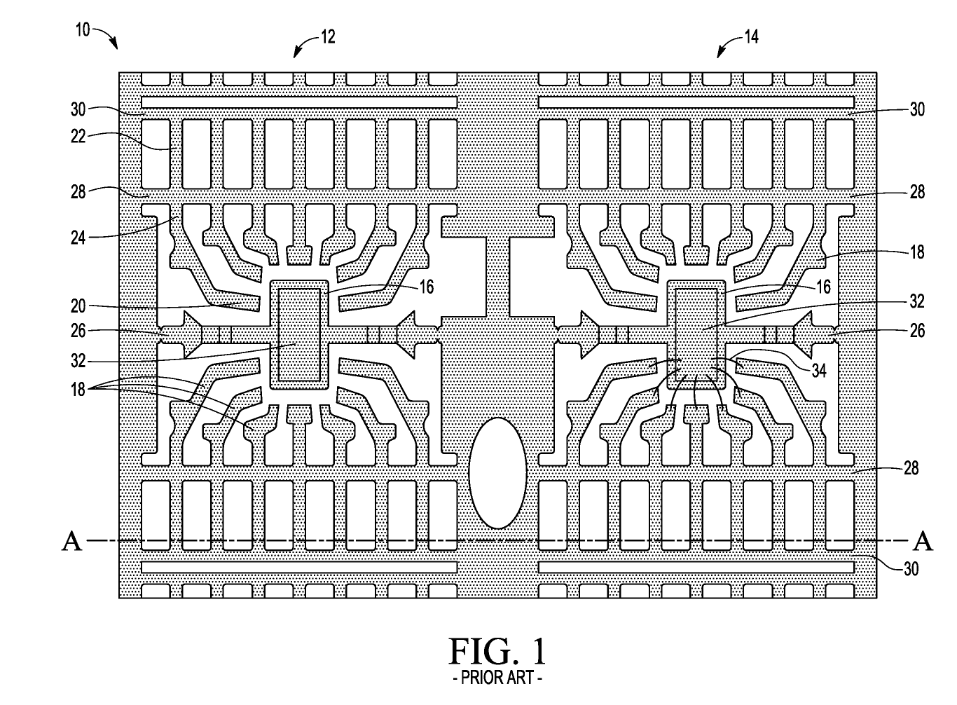

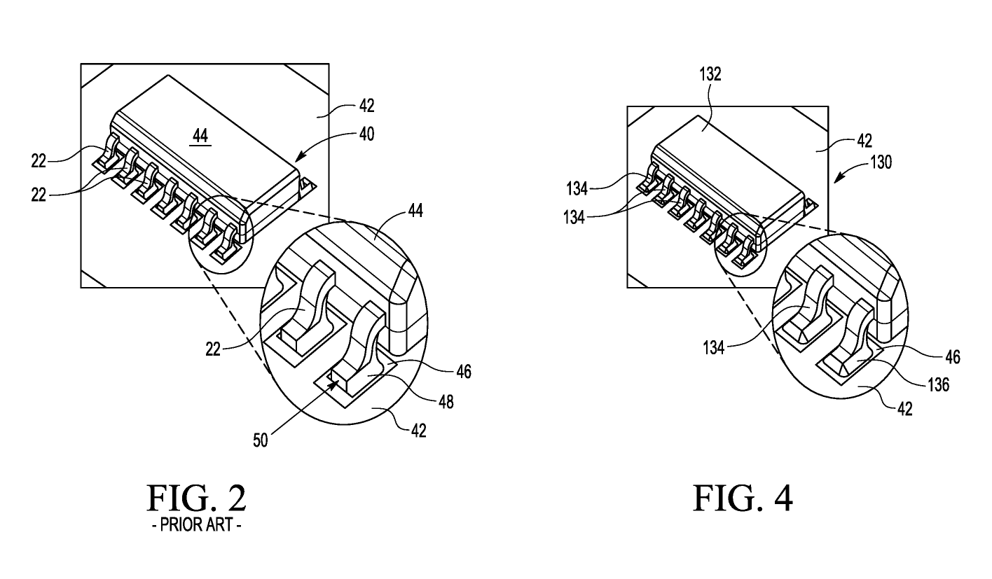

The lead frames 102 and 104 include at least one tie bar that extends from a side of the central area 106 that is adjacent to the at least one lateral side of the central area 106 from which the leads 108 extend, in order to provide support to the die pad 106. In the embodiment shown, the die pads 106 are attached to the central frame with tie bars 116. A dam bar 118 extends perpendicular to the leads 108 and is connected to the central portion 114 of the leads 108, and an end bar 120 also extends generally perpendicular to the leads 108 and parallel to the dam bar 118. The tie bar 116 is generally perpendicular to the leads 108 and parallel to the dam bar 118 and the end bar 120. However, unlike the conventional lead frames 102 and 104 of FIG. 1, the distal ends 112 of the leads 108 are not connected or attached to the end bar 120. Rather, the end bar 120 is located near to, but spaced from, the distal ends 112 of the leads 108. The lead frames 102 and 104 also include one or more connection bars 122 that extend from the end bar 120 to the dam bar 118. In the presently preferred embodiment, the connection bars 122 are temporary, and are cut away during trim and form.

During the assembly process, dies 124 are attached to the die receiving areas 106 of the lead frames 102 and 104 using a die attach material, such as an adhesive or adhesive tape, as is known in the art. In one embodiment, the adhesive is thermally conductive, so that heat generated by the semiconductor die 124 can be dissipated through the die pad 106. In another embodiment, the adhesive is both electrically and thermally conductive for providing additional connection between the semiconductor die 124 and the die pad 106. In one embodiment, the adhesive comprises an epoxy paste that is printed onto the die pad 106. After the semiconductor die 124 is attached to the die receiving area 106, the adhesive is cured so that the semiconductor die 124 is securely fastened to the receiving area 106.

The semiconductor die 124 may be any type of die, such as a sensor die, a power die, an application specific integrated circuit (ASIC), etc. The semiconductor die 124 may have an active region on one side thereof and a non-active region on an opposite side. In the presently preferred embodiment, the semiconductor die 124 is placed on the die pad 106 such that the non-active region side faces the die pad 106. In another embodiment, the active region side of the semiconductor die 124 can be configured to face the die pad 106. In applications where the semiconductor die 124 generates heat (e.g., a power die), the die pad 106 can be used to dissipate the heat through contact between the active region side of the semiconductor die 124 and the die pad 106.

When the semiconductor die 124 is mounted on the die pad 106 with its non-active region side attached to the die pad 106, then bond wires 126 are used to electrically connect the semiconductor die 124 to the leads 108. That is, the electrodes on the active side surface of the semiconductor die 124 are electrically connected to the proximal ends 110 of the leads 108 with the bond wires 126. The bond wires 126 can be any kind of bond wires, such as copper or gold, and may be coated or uncoated.

It will be understood by those of skill in the art that the electrical connection of the semiconductor die 124 to the leads 108 is not limited to the above-mentioned wire bonding. In alternative embodiments, clip bonding, flip-chip, etc. also may be used. For example, in one embodiment the semiconductor die 124 is attached to the lead frame 104 with the die bond pads facing the proximal ends 110 of the leads 108, and electrically connected thereto with conductive adhesive.

After attaching and electrically connecting the semiconductor die 124 to the lead frame 104, the die 124, bond wires 126 and proximal ends 110 of the leads 108 are covered with a molding compound (not shown), where the molding compound extends to the dam bar 118. The molding compound provides electrical and mechanical protection to the semiconductor die 124, the lead frame 104 and the connections 126 therebetween. In one embodiment, the molding compound comprises an epoxy-resin composition, for example a C-stage plastic material (Resite). The molding compound is applied such that it covers and seals the semiconductor die 1124 and at least part of the lead frame 104. The molding compound is subsequently cured to be physically hard, so that the semiconductor die 124, the proximal ends 110 of the leads 108, and the bond wires 126 covered by the molding compound are protected from potential environmental influences like moisture and dust, as well as mechanical damage. The molding compound may be formed over the die 124 using known methods, such as transfer molding.

After molding, the lead frame 104 is trimmed, whereby the dam bar 118 is cut away, and the end bar 120 is separated from the assembly such as by cutting along line B-B, which separates the connection bars 122 from the end bar 120. The connection bars 122 also preferably are cut away from the dam bar 118 at the same time as when the dam bar 118 is trimmed (when separating the leads 108).

FIG. 4 shows a semiconductor device 130 in accordance with an embodiment of the present invention being mounted on the PCB 42. The semiconductor device 130 comprises a molded body 132 and leads 134 that extend outwardly from the molded body 132. That is, the leads 134 comprise the distal ends 112 of the leads 108 shown in FIG. 3. The leads 134 are electrically connected to the pads 46 of the PCB 42 with solder 136. Since the distal ends 112 of the leads 108 were not cut from the end bar 120, the lead tips were not trimmed and thus, the lead tips remain plated and the underlying copper base is not exposed. Therefore, the leads 134 are readily soldered to the solder pads 46 of the PCB 42. As illustrated, the solder 136 covers the lead tip.

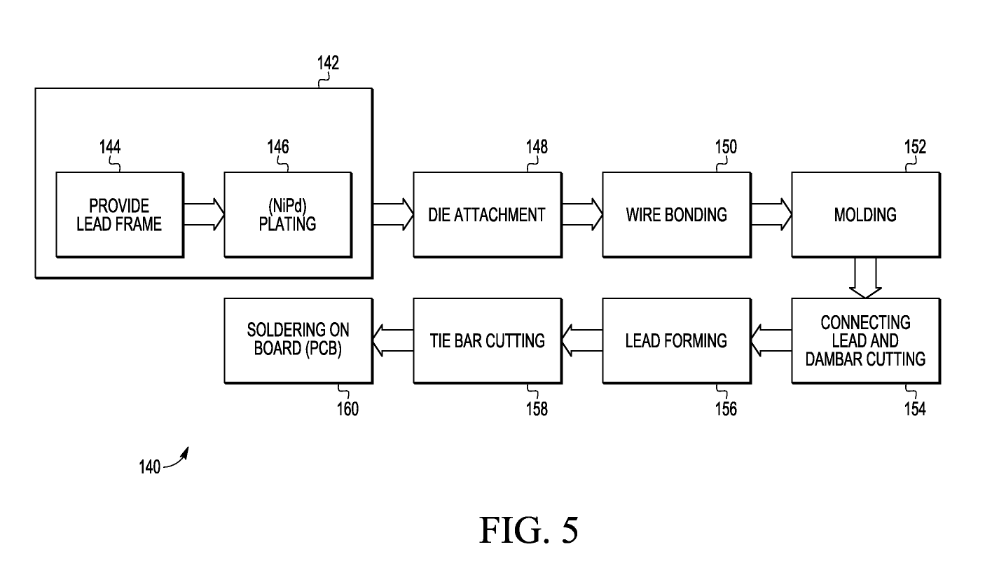

FIG. 5 is a flow diagram 140 illustrating steps of assembling a semiconductor device in accordance with an exemplary embodiment of the present invention. In a first step, 142, a first sub-step 144 of providing a lead frame is performed. The lead frame preferably is one of a strip of lead frames, and includes a central area for receiving an integrated circuit die, and a plurality of leads that extend away from at least one lateral side of the central area, as shown and described above with reference to FIG. 3. As previously discussed, the leads each have a proximal end near to the central receiving area, a distal end, and a central portion connecting the proximal and distal ends. The lead frame further comprises a dam bar that extends generally perpendicular to the leads and connects the leads at the central portions thereof, an end bar that extends generally perpendicular to the leads and parallel to the dam bar, wherein the end bar is located near to, but spaced from, the distal ends of the leads, and one or more connection bars extending from the end bar to the dam bar. At sub-step 146, the lead frame strip or at least the distal ends of the leads of each lead frame are plated with a non-corroding material, such as NiPd. It will be understood by those of skill in the art that the plated lead frame in accordance with embodiments of the present invention may be received from a lead frame supplier rather than the device assembly factory actually forming the lead frames on a strip or in an array and then plating the strip or array.

At step 148, an integrated circuit die is attached to the central area with a die attach adhesive, and then electrodes on a planar surface of the integrated circuit die are electrically connected to the proximal ends of the leads, such as with bond wires, at step 150.

At step 152, the integrated circuit die, the electrical connections, and the proximal ends of the leads are covered with a molding compound. At step 154, the connection bars 122 (see FIG. 3) of the lead frame are cut away, such as with a saw, while the dam bar also is cut away, such as by stamping. Cutting away the connection bars 122 separates the lead frame assembly from the end bars too. At step 156, the portions of the leads that extend outwardly from the molded body are formed to a desired shape, such as by a gull-wing shape, by bending. At step 158, the lead frame assemblies are separated from adjacent assemblies by cutting the tie bars.

Finally, at step 160, the fully assembled semiconductor device may be attached to a PCB, as described above with reference to FIG. 4. And because the distal ends of the leads are not cut or trimmed as part of the assembly process, the lead tips remain coated with the NiPd layer, and thus, good solder joints may be formed when connecting the device to the PCB.

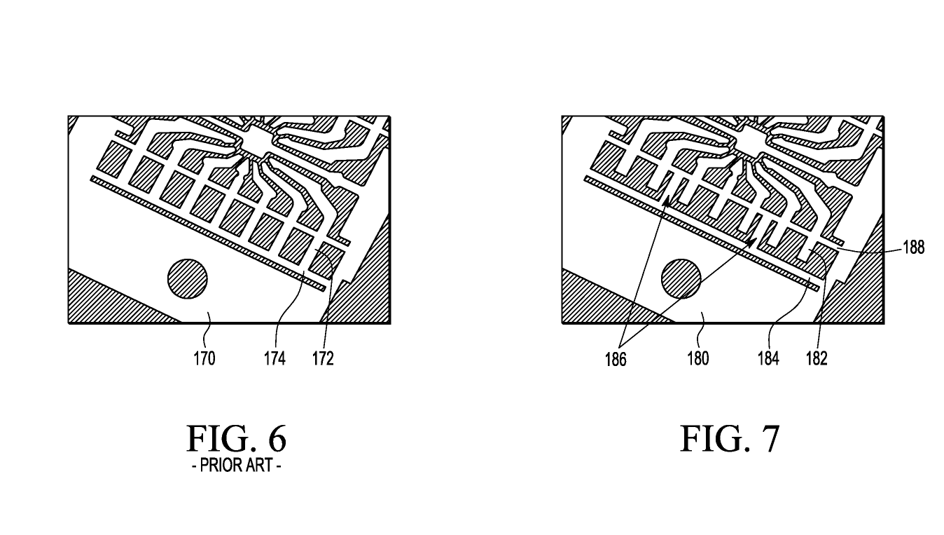

In order to once again highlight the difference between the conventional lead frame and a lead frame of the present invention, FIG. 6 is an enlarged drawing of a portion of a conventional lead frame 170, and FIG. 7 is an enlarged drawing of a portion of a lead frame 180 in accordance with an embodiment of the present invention. In FIG. 6, distal ends 172 of the leads are physically connected to an end bar 174, while in FIG. 7, distal ends 182 of the leads are not connected to an end bar 184. Instead, the lead frame 180 is provided with stability by having connection bars 186 that extend between the end bar 184 and a dam bar 188.

The use of the terms “a” and “an” and “the” and similar referents in the context of describing the subject matter (particularly in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein.

Furthermore, the foregoing description is for the purpose of illustration only, and not for the purpose of limitation, as the scope of protection sought is defined by the claims as set forth hereinafter together with any equivalents thereof entitled to. The use of any and all examples, or exemplary language (e.g., “such as”) provided herein, is intended merely to better illustrate the subject matter and does not pose a limitation on the scope of the subject matter unless otherwise claimed. The use of the term “based on” and other like phrases indicating a condition for bringing about a result, both in the claims and in the written description, is not intended to foreclose any other conditions that bring about that result. No language in the specification should be construed as indicating any non-claimed element as essential to the practice of the invention as claimed.

Preferred embodiments are described herein, including the best mode known to the inventor for carrying out the claimed subject matter. Of course, variations of those preferred embodiments will become apparent to those of ordinary skill in the art upon reading the foregoing description. The inventor expects skilled artisans to employ such variations as appropriate, and the inventor intends for the claimed subject matter to be practiced otherwise than as specifically described herein. Accordingly, this claimed subject matter includes all modifications and equivalents of the subject matter recited in the claims appended hereto as permitted by applicable law. Moreover, any combination of the above-described elements in all possible variations thereof is encompassed unless otherwise indicated herein or otherwise clearly contradicted by context.

1. A lead frame for a semiconductor device, the lead frame comprising:
a central area for receiving an integrated circuit die;
a plurality of leads that extend away from at least one lateral side of the central area, wherein the leads each have a proximal end near to the central area, a distal end, and a central portion connecting the proximal and distal ends;
a dam bar that extends generally perpendicular to the leads and connects the leads at the central portions thereof;
an end bar that extends generally perpendicular to the leads and parallel to the dam bar, wherein the end bar is located near to, but spaced from, the distal ends of the leads;
a tie bar that supports the central area, the tie bar extending from two opposing sides of the central area that are adjacent to the at least one lateral side of the central area from which the leads extend, wherein the tie bar is generally perpendicular to the leads and parallel to the dam bar and the end bar; and
one or more connection bars extending from the end bar to the dam bar, wherein the connection bars terminate at the end bar, and wherein the connection bar provides support to the dam bar,
wherein the lead frame is comprised of copper, and at least the distal ends of the leads are plated with a non-corroding material.

2. The lead frame of claim 1, wherein during assembly of the semiconductor device, the one or more connection bars, the dam bar, and the end bar are cut away from the lead frame.

3. (canceled)

4. The lead frame of claim 1, wherein the non-corroding material comprises Nickel and Palladium.

5. The lead frame of claim 1, wherein the central area comprises a pad for receiving an integrated circuit die.

6. (canceled)

7. The lead frame of claim 1, wherein the lead frame is one of a strip of lead frames formed from a single piece of metal foil.

8. A method of assembling a semiconductor device, the method comprising:
providing a lead frame having a central area for receiving an integrated circuit die, and a plurality of leads that extend away from at least one lateral side of the central area, wherein the leads each have a proximal end near to the central receiving area, a distal end, and a central portion connecting the proximal and distal ends;
wherein the lead frame further comprises a dam bar that extends generally perpendicular to the leads and connects the leads at the central portions thereof, an end bar that extends generally perpendicular to the leads and parallel to the dam bar, wherein the end bar is located near to, but spaced from, the distal ends of the leads, a tie bar that supports the central area, the tie bar extending from two opposing sides of the central area that are adjacent to the at least one lateral side of the central area from which the leads extend, wherein the tie bar is generally perpendicular to the leads and parallel to the dam bar and the end bar, and one or more connection bars extending from the end bar to the dam bar, wherein the connection bars terminate at the end bar, and
wherein at least the distal ends of the leads are plated with a non-corroding material;
attaching an integrated circuit die within the central area;
electrically connecting electrodes on a planar surface of the integrated circuit die with the proximal ends of the leads;
covering the integrated circuit die, the electrical connections, and the proximal ends of the leads with a molding compound; and
trimming the lead frame by cutting the one or more connection bars, the dam bar, and the end bar away,
wherein the trimming step does not cut the distal ends of the leads, so the distal ends of the leads remain plated after assembly of the semiconductor device.

9. (canceled)

10. The method of claim 8, wherein the electrodes of the integrated circuit are electrically connected to respective proximal ends of the leads with bond wires.
